(19) United States
(12) Patent Application Publication
(10) Pub. No.: US 2025/0157845 A1
(43) Pub. Date: May 15, 2025

(54) ELECTROSTATIC CHUCK AND SUBSTRATE PROCESSING APPARATUS

(71) Applicant: Tokyo Electron Limited, Tokyo (JP)

(72) Inventor: Masanori SATO, Miyagi (JP)

(73) Assignee: Tokyo Electron Limited, Tokyo (JP)

(21) Appl. No.: 19/006,650

(22) Filed: Dec. 31, 2024

Related U.S. Application Data
(63) Continuation of application No. PCT/JP2023/032079, filed on Sep. 1, 2023.

(30) Foreign Application Priority Data
Sep. 12, 2022 (JP) 2022-144886

(51) Int. Cl. H01L 21/683; H01J 37/32

(52) U.S. Cl. CPC H01L 21/6833; H01J 37/32715

(57) ABSTRACT

To provide an electrostatic chuck and a substrate processing apparatus that suppress residual attraction of a substrate. The electrostatic chuck including a dielectric and an electrode provided inside the dielectric, in which the dielectric has a first main surface, a contact support that protrudes beyond the first main surface and makes contact with a rear surface of a substrate to support the substrate, and groove portions provided between the first main surface and the contact support to surround the contact support.

### CROSS-REFERENCE TO RELATED APPLICATIONS

This application is a bypass continuation application of international application No. PCT/JP2023/032079 having an international filing date of Sep. 1, 2023, and designating the United States, the international application being based upon and claiming the benefit of priority from Japanese Patent Application No. 2022-144886, filed on Sep. 12, 2022, the entire contents of each are incorporated herein by reference.

### TECHNICAL FIELD

The present disclosure relates to an electrostatic chuck and a substrate processing apparatus.

### BACKGROUND

JP2020-129632A discloses a holding apparatus including a ceramic member in which a recess portion and a plurality of protruding portions (outer peripheral seal bands and columnar-shaped protruding portions) are formed on an attraction surface.

JP2013-149935A discloses that residual charges accumulate on a surface of the electrostatic chuck, thereby causing a substrate to be residually attracted.

### CITATION LIST

### Patent Documents

Patent Literature 1: JP2020-129632A
Patent Literature 2: JP2013-149935A

### SUMMARY

In one aspect, the present disclosure provides an electrostatic chuck and a substrate processing apparatus that suppresses residual attraction of a substrate.

In order to solve the above problem, according to one aspect, there is provided an electrostatic chuck including a dielectric and an electrode provided inside the dielectric, in which the dielectric has a first main surface, a contact support that protrudes beyond the first main surface and makes contact with a rear surface of a substrate to support the substrate, and groove portions provided between the first main surface and the contact support to surround the contact support.

According to one aspect, it is possible to provide an electrostatic chuck and a substrate processing apparatus that suppress residual attraction of a substrate.

### BRIEF DESCRIPTION OF DRAWINGS

FIG. 1 is an example of a view illustrating a configuration example of a capacitively-coupled plasma processing apparatus.

FIG. 2 is an example of a plan view of the electrostatic chuck according to one or more embodiments.

FIG. 3 is an example of a cross-sectional view of the electrostatic chuck taken along line A-A according to one or more embodiments.

FIG. 4 is an example of a plan view of an electrostatic chuck according to a reference example.

FIG. 5 is an example of a cross-sectional view of the electrostatic chuck taken along line B-B according to the reference example.

FIG. 6 is an example of a partially enlarged cross-sectional view illustrating a substrate holding state in the electrostatic chuck according to one or more embodiments.

FIG. 7 is an example of a partially enlarged cross-sectional view illustrating a substrate holding state in the electrostatic chuck according to the reference example.

FIG. 8 is another example of the partially enlarged cross-sectional view illustrating the substrate holding state in the electrostatic chuck according to one or more embodiments.

### DETAILED DESCRIPTION

Hereinafter, embodiments for implementing the present disclosure will be described with reference to the drawings. In the respective drawings, the same components will be denoted by the same reference numerals, and overlapping descriptions thereof may be appropriately omitted.

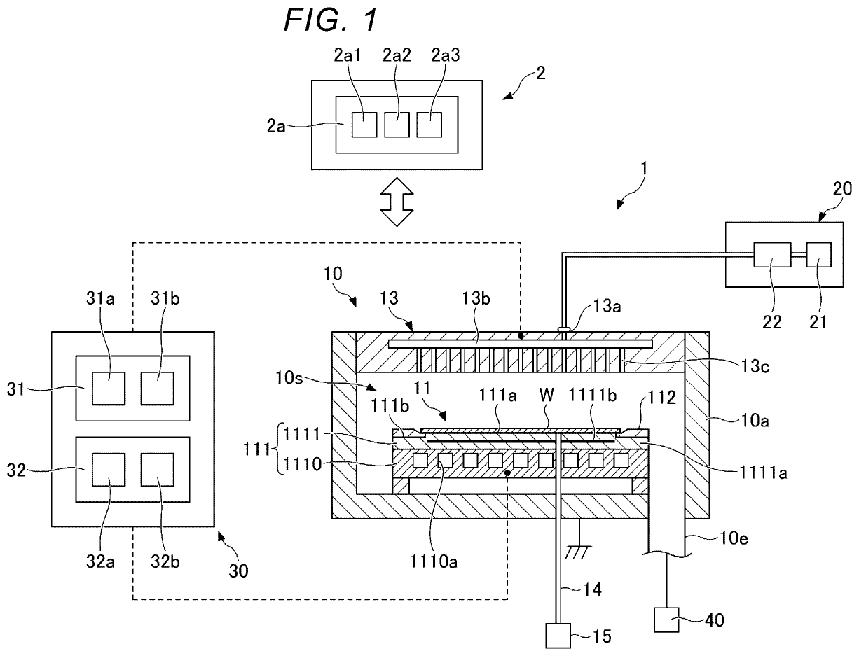

Hereinafter, a configuration example of a plasma processing system will be described. FIG. 1 is an example of a diagram showing a configuration example of a capacitively-coupled plasma processing apparatus (a substrate processing apparatus) 1.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one or more embodiments, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one or more embodiments, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one or more embodiments, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one or more embodiments, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one or more embodiments, the flow path 1110a is formed inside the base 1110, and one or more heaters are disposed in the ceramic member 1111a of the electrostatic chuck 1111. Further, the substrate support 11 may include a heat transfer gas supply 15 configured to supply a heat transfer gas to a gap between a rear surface of the substrate W and the central region 111a. The heat transfer gas supply 15 supplies a heat transfer gas such as a He gas, for example, between the rear surface of the substrate W placed on the electrostatic chuck 1111 and the first main surface (a dug-in surface 121 to be described later) of the electrostatic chuck 1111 through the flow path 14.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one or more embodiments, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying the bias RF signal to at least one lower electrode can generate a bias potential in the substrate W to attract an ionic component in the formed plasma to the substrate W.

In one or more embodiments, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one or more embodiments, the source RF signal has a frequency in the range of 10 MHz to 150 MHz. In one or more embodiments, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one or more embodiments, the bias RF signal has a lower frequency than the frequency of the source RF signal. In one or more embodiments, the bias RF signal has a frequency in the range of 100 kHz to 60 MHz. In one or more embodiments, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one or more embodiments, the first DC generator 32a is configured to be connected to at least one lower electrode to generate the first DC signal. The generated first bias DC signal is applied to at least one lower electrode. In one or more embodiments, the second DC generator 32b is configured to be connected to at least one upper electrode to generate a second DC signal. The generated second DC signal is applied to at least one upper electrode.

In various embodiments, at least one of the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one or more embodiments, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

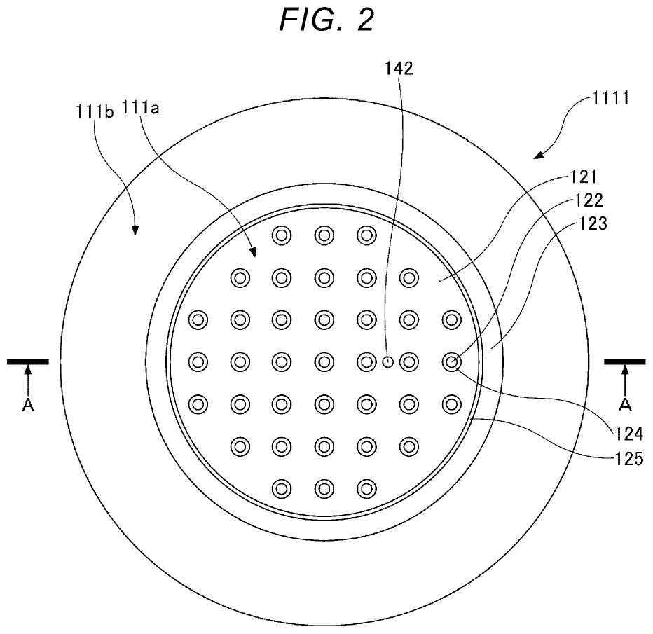

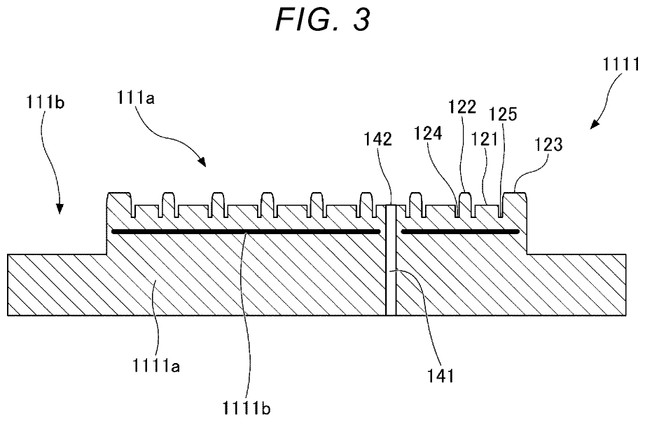

Next, the electrostatic chuck 1111 will be further described with reference to FIGS. 2 and 3. FIG. 2 is an example of a plan view of the electrostatic chuck 1111 according to one or more embodiments. FIG. 3 is an example of a cross-sectional view of the electrostatic chuck 1111 taken along line A-A according to one or more embodiments.

The electrostatic chuck 1111 includes a ceramic member 1111a and an electrostatic electrode 1111b. The ceramic member 1111a is formed of a dielectric (that is, the ceramic member 1111a can be designated as “dielectric”). The electrostatic electrode 1111b is disposed in the ceramic member 1111a.

The central region 111a of the electrostatic chuck 1111 has a dug-in surface (first main surface) 121, dots 122 (e.g., protrusions), and a seal band 123.

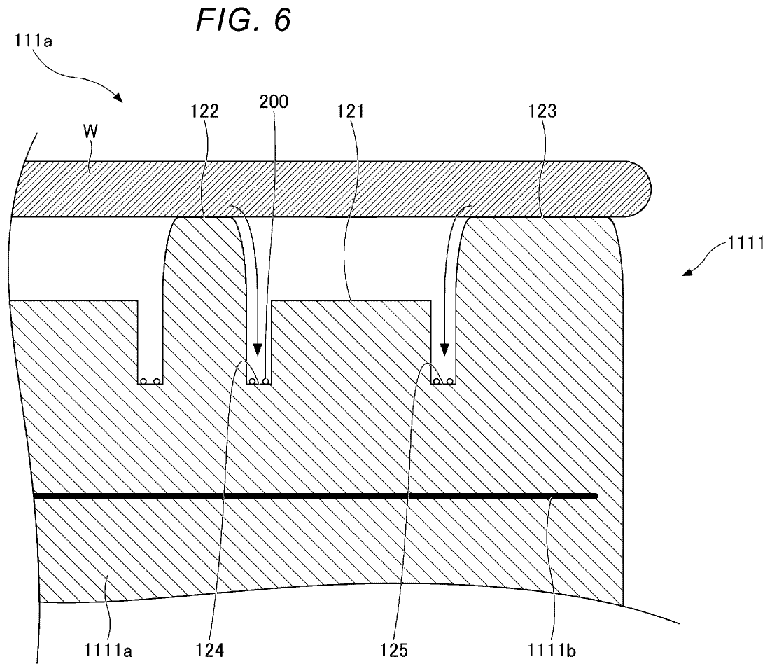

The dug-in surface 121 is a surface dug deeper than an upper surface of the dot 122 (a placement surface of the substrate W) and an upper surface of the seal band 123 (a placement surface of the substrate W). Further, the dug-in surface 121 is a surface that faces the rear surface of the substrate W while being spaced apart from the rear surface of the substrate W when the substrate W is placed on the electrostatic chuck 1111 (see FIG. 6 to be described later). A surface of the dug-in surface 121 is a processed surface subjected to a blasting process and a polishing process. The surface of the dug-in surface 121 is, for example, a processed surface having an arithmetic average roughness Ra of 0.1 (μm).

Further, the electrostatic chuck 1111 has a flow path 141 and an opening 142. The flow path 141 is formed through the electrostatic chuck 1111 to supply the heat transfer gas from the heat transfer gas supply 15 (see FIG. 1) through the flow path 14 (see FIG. 1). The opening 142 is formed in the dug-in surface 121.

The dots 122 and the seal band 123 are formed in the central region 111a of the electrostatic chuck 1111 as contact supports protruding beyond the dug-in surface 121.

The dot 122 is formed in a substantially columnar shape protruding from the dug-in surface 121. A plurality of dots 122 are formed in an inner region of an annular-shaped seal band 123 formed at a peripheral portion of the central region 111a in a plan view of the electrostatic chuck 1111 (see FIG. 2). When the substrate W is placed on the electrostatic chuck 1111 (see FIG. 6 to be described later), the upper surfaces of the dot 122 makes contact with the rear surface of the substrate W and the dot 122 supports the inner region of the substrate W. The upper surface of the dot 122 is a processed surface subjected to the polishing process. The upper surface of the dot 122 is, for example, a processed surface having an arithmetic average roughness Ra of 0.01 (μm).

The seal band 123 protrudes from the dug-in surface 121 and is formed in an annular shape along an outer periphery of the central region 111a. When the substrate W is placed on the electrostatic chuck 1111 (see FIG. 6 to be described later), the upper surface of the seal band 123 makes contact with the rear surface of the substrate W and the seal band 123 supports an outer region of the substrate W. The upper surface of the seal band 123 is a processed surface subjected to the polishing process. The upper surface of the seal band 123 is, for example, a processed surface having an arithmetic average roughness Ra of 0.01 (μm).

Further, when the substrate W is placed on the electrostatic chuck 1111 (see FIG. 6 to be described later), the seal band 123 forms a space (gap) by the rear surface of the substrate W, the dug-in surface 121 of the electrostatic chuck 1111, and the inner peripheral surface of the seal band 123. The heat transfer gas supplied from the heat transfer gas supply 15 is supplied to the space from the opening 142 formed in the dug-in surface 121 through the flow path 14 and the flow path 141.

Groove portions 124 and 125 dug deeper than the dug-in surface 121 are formed in the central region 111a of the electrostatic chuck 1111.

The groove portion 124 is formed to surround the dot 122. In other words, the groove portion 124 is formed between the upper surface of the dot 122 and the dug-in surface 121. Further, the groove portion 124 is formed directly on the electrostatic electrode 1111b.

The groove portion 125 is formed to surround (i.e., surrounds) the inner peripheral side of the seal band 123. In other words, the groove portion 125 is formed between the upper surface of the seal band 123 and the dug-in surface 121. Further, the groove portion 125 is formed directly on the electrostatic electrode 1111b.

Further, the electrostatic chuck 1111 has a plurality of contact supports (the dots 122 and the seal band 123), and the groove portions 124 and 125 are provided corresponding to the plurality of contact supports (the dots 122 and the seal band 123), respectively. Further, the plurality of groove portions 124 and 125 are continuously provided to surround the contact supports. However, the groove portions 124 and 125 may be discretely provided. In other words, one contact support 122 or 123 may be provided to be surrounded by the plurality of groove portions 124 and 125.

Further, bottom surfaces of the groove portions 124 and 125 are formed at positions closer to the electrostatic electrode 1111b than the dug-in surface 121. Further, the bottom surfaces of the groove portions 124 and 125 are formed at positions closer to the electrostatic electrode 1111b than a contact surface on which the substrate W is placed (the upper surface of the dot 122 and the upper surface of the seal band 123). Further, the dug-in surface 121 is formed at a position closer to the electrostatic electrode 1111b than the contact surface on which the substrate W is placed (the upper surface of the dot 122 and the upper surface of the seal band 123).

Widths of the groove portions 124 and 125 are preferably, for example, 5 μm or greater and 150 μm or less. When the widths of the groove portions 124 and 125 are set to 150 μm or less, it is possible to secure a large area of the dug-in surface 121 that contributes to an attraction force when the substrate W is electrostatically attracted and held. Further, when the widths of the groove portions 124 and 125 are set to 5 μm or greater, it can be easy to form the groove portions 124 and 125. The groove portions 124 and 125 are formed by, for example, groove cutting using a laser.

Further, in a plan view (see FIG. 2), areas of the groove portions 124 and 125 are preferably 10% or less of the area of the dug-in surface 121.

Further, the width of the groove portion 125 is preferably wider than the width of the groove portion 124. Specifically, the width of the groove portion 125 is preferably 1.5 times wider than the width of the groove portion 124.

Depths of the groove portions 124 and 125 are preferably at least twice or more the roughness of the dug-in surface 121. Further, the depths of the groove portions 124 and 125 are preferably, for example, 10 μm or greater and 100 μm or less.

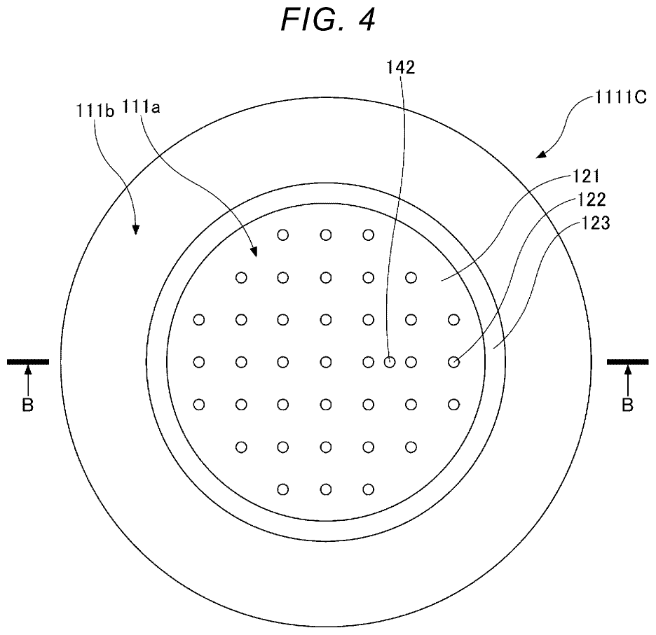

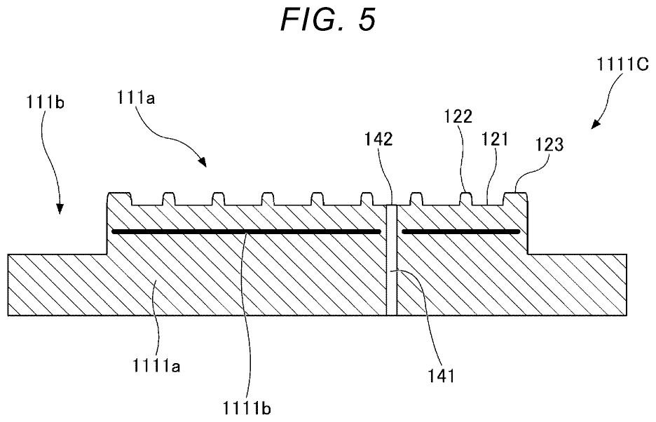

Next, an electrostatic chuck 1111C according to a reference example will be described with reference to FIGS. 4 and 5. FIG. 4 is an example of a plan view of the electrostatic chuck 1111C according to the reference example. FIG. 5 is an example of a cross-sectional view of the electrostatic chuck 1111C taken along line B-B according to the reference example.

A central region 111a of the electrostatic chuck 1111C according to the reference example has a dug-in surface 121, dots 122 (e.g., protrusions), and a seal band 123. That is, the electrostatic chuck 1111C according to the reference example is different from the electrostatic chuck 1111 according to one or more embodiments in that the groove portions 124 and 125 are not formed. Other configurations are similar to each other, and overlapping descriptions thereof will be omitted.

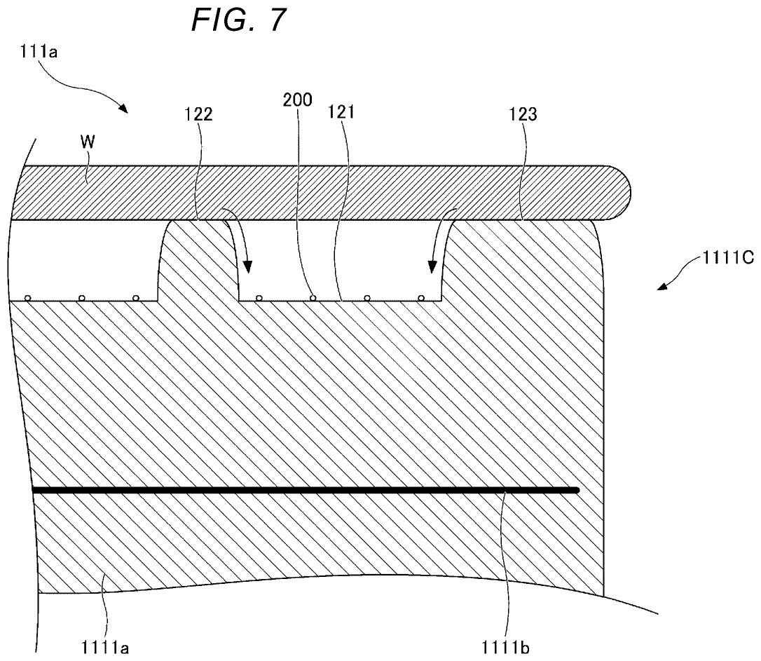

Next, the electrostatic chuck 1111 according to one or more embodiments will be further described in comparison with the electrostatic chuck 1111C according to the reference example. FIG. 6 is an example of a partially enlarged cross-sectional view illustrating a substrate holding state in the electrostatic chuck 1111 according to one or more embodiments. FIG. 7 is an example of a partially enlarged cross-sectional view illustrating a substrate holding state in the electrostatic chuck 1111C according to the reference example.

When the substrate W is attracted, an attraction voltage (for example, 2.5 kV) is applied to the electrostatic electrode 1111b, so that a charge is induced in the substrate W, a Coulomb force is generated by a potential difference between the induced charge of the substrate W and the electrostatic electrode 1111b, and the substrate W is electrostatically attracted to the electrostatic chuck 1111 (1111C). Further, when the application of the attraction voltage to the electrostatic electrode 1111b is stopped, the attraction is released.

In this case, a reaction by-product film may be formed on the surface of the electrostatic chuck 1111 (1111C) when the substrate W is processed. When insulation properties of the reaction by-product film are low, in a high-temperature process or a long-time process, a charge 200 leaks from the contact surface on which the substrate W is placed (the upper surface of the dot 122 and the upper surface of the seal band 123) as indicated by arrows of FIGS. 6 and 7, and the charge 200 move downward by the attraction voltage applied to the electrostatic electrode 1111b or a self-bias voltage of plasma.

In the electrostatic chuck 1111C illustrated in FIG. 7, the charge 200 leaking from the contact surface on which the substrate W is placed (the upper surface of the dot 122 and the upper surface of the seal band 123) moves to the dug-in surface 121 that does not make contact with the substrate W by the attraction voltage applied to the electrostatic electrode 1111b, and the charge 200 is accumulated in the dug-in surface 121.

As a result, the Coulomb force is generated by the charge of the substrate W and the charge 200 accumulated in the dug-in surface 121, and even if the application of the attraction voltage to the electrostatic electrode 1111b is stopped, the electrostatic attraction between the substrate W and the electrostatic chuck 1111C may be maintained (residual attraction occurs). Meanwhile, in order to reduce the charge leaking from the substrate W to the contact support, it is conceivable to reduce contact area between the contact support (the dots 122 and the seal band 123) and the substrate W. However, the attraction force to the substrate W and sealability (e.g., ability to seal) of the heat transfer gas may be reduced.

Further, the attraction voltage is continuously applied to the electrostatic electrode 1111b and the charge 200 accumulated in the dug-in surface 121 is increased, so that the Coulomb force between the substrate W and the electrostatic chuck 1111C is reduced. Accordingly, even in a state where the attraction voltage is applied to the electrostatic electrode 1111b, the substrate W may be peeled off from the electrostatic chuck 1111C by a pressure of the heat transfer gas.

In contrast, in the electrostatic chuck 1111 illustrated in FIG. 6, the charge 200 leaking from the contact surface on which the substrate W is placed (the upper surface of the dot 122 and the upper surface of the seal band 123) moves to the bottom surfaces of the groove portions 124 and 125 by the attraction voltage applied to the electrostatic electrode 1111b, and the charge 200 is accumulated in the bottom surfaces of the groove portions 124 and 125. Further, the dug-in surface 121 is formed at a position (high position) away from the bottom surfaces of the groove portions 124 and 125 when viewed from the electrostatic electrode 1111b. Therefore, the charge 200 that has moved to the bottom surfaces of the groove portions 124 and 125 does not move to the dug-in surface 121 by the attraction voltage or the like that is applied to the electrostatic electrode 1111b.

In this case, the Coulomb force is proportional to an area of a surface on which the charge 200 is accumulated, and is inversely proportional to a distance between the rear surface of the substrate W and the surface in which the charge 200 is accumulated. The surfaces of the electrostatic chuck 1111 in which the charge 200 is accumulated are the bottom surfaces of the groove portions 124 and 125. Further, the surface of the electrostatic chuck 1111C in which the charge 200 is accumulated is the dug-in surface 121. Therefore, the electrostatic chuck 1111 can reduce the area of the surface in which the charge 200 is accumulated, and can reduce the Coulomb force. Further, the electrostatic chuck 1111 can increase the distance between the rear surface of the substrate W and the surface in which the charge 200 is accumulated, so that the Coulomb force can be reduced. As a result, the residual attraction force can be reduced.

For example, in a case where the areas of the groove portions 124 and 125 are set to 10% of the area of the dug-in surface 121 and the widths of the groove portions 124 and 125 are set to 70 μm, when the depths of the groove portions 124 and 125 (the distance between the dug-in surface 121 and the bottom surfaces of the groove portions 124 and 125) are 10 to 20 μm, the residual attraction force is set to about 1/40, when the depths of the groove portions 124 and 125 are 20 to 50 μm, the residual attraction force is set to about 1/45, and when the depths of the groove portions 124 and 125 are 50 to 100 μm, the residual attraction force is set to about 1/50. Further, in a case where the widths of the groove portions 124 and 125 are set to 700 μm, when the depths of the groove portions 124 and 125 are 10 to 20 μm, the residual attraction force is set to about 1/100, when the depths of the groove portions 124 and 125 are 20 to 50 μm, the residual attraction force is set to about 1/110, and when the depths of the groove portions 124 and 125 are 50 to 100 μm, the residual attraction force is set to about 1/150.

Further, even in a state where the attraction voltage is continuously applied to the electrostatic electrode 1111b and the charge 200 is accumulated in the bottom surfaces of the groove portions 124 and 125, the dug-in surface 121 can be in a state where the charge 200 is not accumulated therein, and the substrate W can be electrostatically attracted by the dug-in surface 121. Accordingly, it is possible to suppress the substrate W from peeling off from the electrostatic chuck 1111C in a state where the attraction voltage is applied to the electrostatic electrode 1111b. Therefore, since the pressure of the heat transfer gas can be secured, cooling properties of the substrate W can be secured. Further, the width of the seal band 123 can be secured, and the sealability of the heat transfer gas can be secured.

Further, when the attraction of the substrate W is released, a process of reducing the residual attraction force is performed by applying a voltage (for example, −500 V), which is opposite to the attraction voltage, to the electrostatic electrode 1111b. In the electrostatic chuck 1111 illustrated in FIG. 6, the charge 200 is accumulated in the bottom surfaces of the groove portions 124 and 125 having a small area, so that a charge density is high. Further, the groove portions 124 and 125 are provided directly on the electrostatic electrode 1111b. Therefore, it is possible to improve efficiency of removing the charge 200 when the process for reducing the residual attraction force is performed.

Further, the width of the groove portion 125 is preferably wider than the width of the groove portion 124. As a result, the charge leaking from the seal band 123 having a large contact area with the substrate W can be accumulated in the groove portion 125.

The groove portions 124 and 125 provided in the electrostatic chuck 1111 have been described. However, the present disclosure is not limited thereto.

Only the groove portion 125 that surrounds the inner peripheral side of the seal band 123 may be formed, and the groove portion 124 that surrounds the dot 122 may be omitted. For example, when the number of dots 122 is small, in other words, when the sum of the areas of the upper surfaces of the plurality of dots 122 making contact with the substrate Wis sufficiently small in comparison with the area of the upper surface of the seal band 123 making contact with the substrate W, the charge leaking from the upper surfaces of the dots 122 is small in comparison with the charge leaking from the upper surface of the seal band 123. In such a configuration, only the groove portion 125 that surrounds the inner peripheral side of the seal band 123 may be formed.

Further, a parallel surface may be provided between the contact surface on which the substrate W is placed (the upper surface of the dot 122 and the upper surface of the seal band 123) and the bottom surfaces of the groove portions 124 and 125. The parallel surface may be formed at the same height as the dug-in surface 121. An area of this parallel surface is formed to be smaller than the area of the dug-in surface 121. Even in such a configuration, the charge 200 leaking from the contact surface on which the substrate W is placed (the upper surface of the dot 122 and the upper surface of the seal band 123) moves to the parallel surface by the attraction voltage or the like applied to the electrostatic electrode 1111b, and furthermore, the charge 200 is accumulated in the bottom surfaces of the groove portions 124 and 125 by moving to the bottom surfaces of the groove portions 124 and 125.

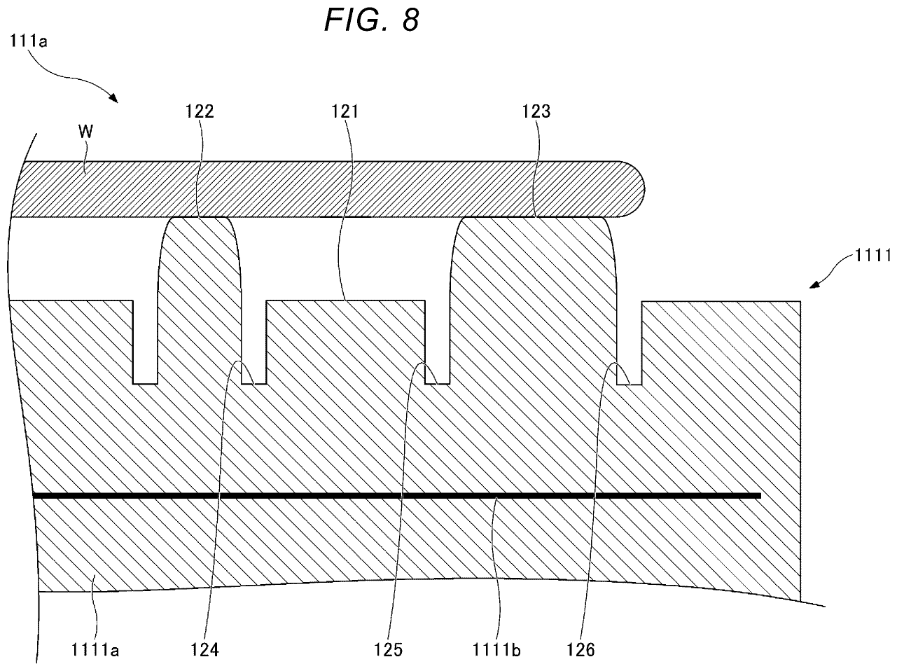

Further, the groove portion 125 is formed to surround the inner peripheral side of the seal band 123. However, the present disclosure is not limited thereto. FIG. 8 is another example of the partially enlarged cross-sectional view illustrating the substrate holding state in the electrostatic chuck 1111 according to one or more embodiments. As illustrated in FIG. 8, a groove portion 126 may be formed to surround the outer peripheral side of the seal band 123.

Further, the electrostatic chuck 1111 has been described as having a configuration in which the substrate W is attracted by the Coulomb force by way of example. However, the present disclosure is not limited thereto, and the electrostatic chuck 1111 may be applied to a configuration in which the substrate W is attracted by a Johnson-Rahbeck effect. In addition, the electrostatic electrode 1111b of the electrostatic chuck 1111 has been described as a unipolar configuration by way of example. However, the present disclosure is not limited thereto, and the electrostatic electrode 1111b may have a multipolar configuration, or may have a unipolar configuration or a bipolar configuration.

The embodiments disclosed above include, for example, the following aspects.

### (Appendix 1)

An electrostatic chuck including:
a dielectric; and
an electrode provided inside the dielectric,
in which the dielectric has
a first main surface,
a contact support that protrudes beyond the first main surface and makes contact with a rear surface of a substrate to support the substrate, and
a groove portion provided between the first main surface and the contact support to surround the contact support.

### (Appendix 2)

The electrostatic chuck according to Appendix 1,

in which the contact support is an annular-shaped seal band formed along a peripheral portion of the first main surface.

### (Appendix 3)

The electrostatic chuck according to Appendix 2, in which the groove portion is provided on an inner peripheral side of the seal band.

### (Appendix 4)

The electrostatic chuck according to Appendix 2 or 3,

in which the groove portion is provided on an outer peripheral side of the seal band.

### (Appendix 5)

The electrostatic chuck according to any one of Appendices 1 to 4,

in which the contact support is a dot formed in a columnar shape.

### (Appendix 6)

The electrostatic chuck according to any one of Appendices 1 to 5,

in which a width of the groove portion is 5 μm or greater and 150 μm or less.

### (Appendix 7)

The electrostatic chuck according to any one of Appendices 1 to 5,

in which a depth of the groove portion is 10 μm or greater and 100 μm or less.

### (Appendix 8)

The electrostatic chuck according to any one of Appendices 1 to 7,
in which the electrostatic chuck has a plurality of contact supports, and
the groove portions are provided for each of the plurality of contact supports.

### (Appendix 9)

The electrostatic chuck according to any one of Appendices 1 to 8,

in which the groove portion is continuously provided to surround the contact support.

### (Appendix 10)

The electrostatic chuck according to any one of Appendices 1 to 8,

in which the groove portions are discretely provided to surround the contact support.

### (Appendix 11)

The electrostatic chuck according to any one of Appendices 1 to 10,
in which the electrostatic chuck has a flow path, and
an opening of the flow path is formed in the first main surface.

### (Appendix 12)

The electrostatic chuck according to Appendix 1,
in which the contact support includes a first contact support formed in an annular shape along a peripheral portion of the first main surface, and a plurality of second contact supports formed in a columnar shape in an inner region of the first contact support, and
the groove portions include a first groove that surrounds the first contact support, and a plurality of second grooves provided for each of the plurality of second contact supports.

### (Appendix 13)

The electrostatic chuck according to any one of Appendices 1 to 12,

in which the groove portion is formed directly on the electrode.

### (Appendix 14)

The electrostatic chuck according to Appendix 13,

in which a bottom surface of the groove portion is formed at a position closer to the electrode than the first main surface.

### (Appendix 15)

A substrate processing apparatus including:

the electrostatic chuck according to any one of Appendices 1 to 14.

As described above, although the plasma processing apparatus 1 has been described above, the present disclosure is not limited to the above-described embodiments and the like, and various modifications and improvements can be made within the scope of the present disclosure described in the claims. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

1. An electrostatic chuck comprising:
a dielectric; and
an electrode provided inside the dielectric,
wherein the dielectric includes
a first main surface,
a contact support that protrudes beyond the first main surface and contacts a rear surface of a substrate to support the substrate, and
groove portions disposed between the first main surface and the contact support to surround the contact support.

2. The electrostatic chuck according to claim 1,
wherein the contact support is an annular-shaped seal band formed along a peripheral portion of the first main surface.

3. The electrostatic chuck according to claim 2,
wherein at least one of the groove portions is provided on an inner peripheral side of the seal band.

4. The electrostatic chuck according to claim 3,
wherein another one of the groove portions is provided on an outer peripheral side of the seal band.

5. The electrostatic chuck according to claim 1,
wherein the contact support is a protrusion formed in a columnar shape.

6. The electrostatic chuck according to claim 1,
wherein a width of each of the groove portions is 5 μm or greater and 150 μm or less.

7. The electrostatic chuck according to claim 1,
wherein a depth of each of the groove portions is 10 μm or greater and 100 μm or less.

8. The electrostatic chuck according to claim 1,
wherein the electrostatic chuck has a plurality of contact supports, and
the groove portions are provided for each of the plurality of contact supports.

9. The electrostatic chuck according to claim 1,
wherein the groove portions surround the contact support.

10. The electrostatic chuck according to claim 1,
wherein the contact support includes a plurality of protrusions and a seal band surrounding the plurality of protrusions, and
the groove portions surround the plurality of protrusions and are disposed within the seal band.

11. The electrostatic chuck according to claim 1,
wherein the electrostatic chuck has a flow path, and
an opening of the flow path is formed in the first main surface.

12. The electrostatic chuck according to claim 1,
wherein the contact support includes a first contact support formed in an annular shape along a peripheral portion of the first main surface, and a plurality of second contact supports formed in a columnar shape in an inner region of the first contact support, and
the groove portions include a first groove that surrounds the first contact support, and a plurality of second grooves provided for each of the plurality of second contact supports.

13. The electrostatic chuck according to claim 1,
wherein the groove portions are formed directly on the electrode.

14. The electrostatic chuck according to claim 13,
wherein a bottom surface of the groove portions is formed at a position closer to the electrode than the first main surface.

15. A substrate processing apparatus comprising:
a processing chamber, including:
a substrate support;
a shower head configured to introduce gas into the processing chamber; and
an exhaust port,
wherein the substrate support includes the electrostatic chuck according to claim 1.

16. The substrate processing apparatus according to claim 15,
wherein the contact support is an annular-shaped seal band formed along a peripheral portion of the first main surface.

17. The substrate processing apparatus according to claim 16,
wherein at least one of the groove portions is provided on an inner peripheral side of the seal band.

18. The substrate processing apparatus according to claim 15,
wherein the electrostatic chuck has a plurality of contact supports, and
the groove portions are provided for each of the plurality of contact supports.

19. The substrate processing apparatus according to claim 15,
wherein the contact support includes a plurality of protrusions and a seal band surrounding the plurality of protrusions, and
the groove portions surround the plurality of protrusions and are disposed within the seal band.

20. The substrate processing apparatus according to claim 15,
wherein the contact support includes a first contact support formed in an annular shape along a peripheral portion of the first main surface, and a plurality of second contact supports formed in a columnar shape in an inner region of the first contact support, and
the groove portions include a first groove that surrounds the first contact support, and a plurality of second grooves provided for each of the plurality of second contact supports.
